(19) United States
(12) Patent Application Publication
(10) Pub. No.: US 2026/0130017 A1
(43) Pub. Date: May 7, 2026

(54) LIGHT EMITTING DIODE AND DISPLAY DEVICE

(71) Applicant: XIAMEN SAN'AN OPTOELECTRONICS CO., LTD., Xiamen (CN)

(72) Inventors: Yenchin WANG, Xiamen (CN); Fu-chun Tsai, Xiamen (CN); Song Yang, Xiamen (CN); Wenjie Xie, Xiamen (CN); Huanshao KUO, Xiamen (CN); Yuren PENG, Xiamen (CN)

(21) Appl. No.: 19/378,254

(22) Filed: Nov. 3, 2025

(30) Foreign Application Priority Data
Nov. 4, 2024 (CN) 202411562270.1

(51) Int. Cl. H10H 20/84; H10H 20/831

(52) U.S. Cl. CPC H10H 20/84; H10H 20/8314

(57) ABSTRACT

Provided are a light emitting diode (LED) and a display device. The LED includes an epitaxial structure and a metal stack structure. The epitaxial structure includes a first semiconductor layer, an active layer, and a second semiconductor layer. The second semiconductor layer, the active layer, and the first semiconductor layer are sequentially etched from a surface of the second semiconductor layer. A part of a remaining portion of the first semiconductor layer after etching defines a first mesa structure. A remaining portion of the second semiconductor layer after etching, a remaining portion of the active layer after etching, and other part of the remaining portion of the first semiconductor layer after etching define a second mesa structure. The metal stack structure is disposed above the first mesa structure and/or the second mesa structure and includes inert metal layers and magnetic metal layers.

### CROSS-REFERENCE TO RELATED APPLICATION

This application claims the priority of Chinese Patent Application No. 202411562270.1, filed on Nov. 4, 2024, which is herein incorporated by reference in its entirety.

### TECHNICAL FIELD

The present disclosure relates to the technical field of semiconductor devices, and particularly to a light emitting diode (LED) and a display device.

### BACKGROUND

A micro-LED (mLED) is a new generation of display technology. Compared with a traditional LED, the mLED shares a same light-emitting principle. However, a size of a single mLED is less than 20 μm, which significantly increases the difficulty of its fabrication. A mass transfer technology for the mLED is key. To accommodate large-area displays, a vast number of mLEDs need to be transferred from a sapphire substrate to a glass panel. A traditional “pick-and-place” method is too inefficient for a large-area transfer within a short time.

Currently, there exists a chip transfer method. This method involves disposing a magnetic metal component within an electrode structure of a chip, i.e., an LED. The chip is then placed in electric and magnetic field environments. During transfer, intensities of magnetic and electric fields are controlled to make the chip move to a preset position of a substrate under the action of magnetic and electric forces, thereby achieving chip transfer. However, the magnetic metal component on the chip is susceptible to damage during a chip fabrication process, which affects reliability and transfer yield of the chip.

### SUMMARY

In view of the aforementioned shortcomings of the related art, objectives of the present disclosure are to provide an LED and a display device, so as to ensure reliability and transfer yield of the LED.

To achieve the above objectives and other related objectives, in a first aspect, the present disclosure provides an LED. The LED includes an epitaxial structure and a metal stack structure. The epitaxial structure includes a first semiconductor layer, an active layer, and a second semiconductor layer. The second semiconductor layer, the active layer, and the first semiconductor layer are sequentially etched downward from a partial surface of the second semiconductor layer. A part of a remaining portion of the first semiconductor layer after etching defines a first mesa structure. A remaining portion of the second semiconductor layer after etching, a remaining portion of the active layer after etching, and other part of the remaining portion of the first semiconductor layer after etching define a second mesa structure. The metal stack structure is disposed above the first mesa structure and/or the second mesa structure. The metal stack structure includes alternately arranged first metal layers and second metal layers. The first metal layer is an inert metal layer, and the second metal layer is a magnetic metal layer.

In a second aspect, the present disclosure further provides a display device. The display device includes an encapsulation substrate and at least one LED disposed on the encapsulation substrate. A side having an electrode layer of each of the at least one LED is a light-emitting side, and a side opposite to the light-emitting side of each of the at least one LED is a backlight side. The backlight side of each of the at least one LED is connected to the encapsulation substrate, and each of the at least one LED is the LED described above.

Compared with the related art, the LED and the display device of the present disclosure at least have the following beneficial effects.

The LED of the present disclosure includes an epitaxial structure and a metal stack structure. The epitaxial structure includes a first semiconductor layer, an active layer, and a second semiconductor layer. The second semiconductor layer, the active layer, and the first semiconductor layer are sequentially and partially etched downward from a partial surface of the second semiconductor layer. A part of a remaining portion of the first semiconductor layer after etching defines a first mesa structure. A remaining portion of the second semiconductor layer after etching, a remaining portion of the active layer after etching, and other part of the remaining portion of the first semiconductor layer after etching define a second mesa structure. The metal stack structure is disposed above the first mesa structure and/or the second mesa structure. The metal stack structure includes alternately arranged first metal layers and second metal layers. Each of the first metal layers is an inert metal layer, and each of the second metal layers is a magnetic metal layer. Since the first metal layer in the LED of the present disclosure is an inert metal layer, it can resist corrosion from etching solutions in a subsequent process, thereby protecting the metal stack structure.

Furthermore, a layer of the metal stack structure closest to the first mesa structure and/or the second mesa structure is a first layer, and an outermost layer of the metal stack structure farthest from the first mesa structure and/or the second mesa structure is a last layer. Both the first layer and the last layer are the first metal layers. By arranging the first metal layers at top and bottom of the metal stack structure, the magnetic metal layers can be encapsulated, protecting the magnetic metal layers and preventing an electrode layer formed on the metal stack structure from detaching in a subsequent process, thereby improving the reliability of the LED.

Furthermore, a volume ratio of the magnetic metal layers within the metal stack structure to the LED is in a range of 0.8% to 1.2%. By controlling a proportion of the magnetic metal layers, chip transfer in a magnetic or electric field can be achieved, improving transfer efficiency.

The display device of the present disclosure includes the aforementioned LED and thus can also achieve the aforementioned technical effects.

### BRIEF DESCRIPTION OF DRAWINGS

FIG. 1 illustrates a schematic structural diagram of an LED according to an embodiment of the present disclosure.

FIG. 2 illustrates a schematic structural diagram of an LED according to another embodiment of the present disclosure.

FIG. 3 illustrates a schematic structural diagram of an LED according to yet another embodiment of the present disclosure.

FIG. 4 illustrates a schematic structural diagram of a metal stack structure of an LED according to an embodiment of the present disclosure.

FIG. 5 illustrates a schematic structural diagram of another metal stack structure of the LED according to the embodiment of the present disclosure.

FIG. 6 illustrates a schematic plan view of an LED according to still yet embodiment of the present disclosure.

FIG. 7 illustrates a cross-sectional view taken along a line A-A′ in FIG. 6.

FIG. 8 illustrates a schematic structural diagram of a display device according to an embodiment of the present disclosure.

### REFERENCE NUMERALS

100. Epitaxial structure; 101. Second semiconductor layer; 102. Active layer; 103. First semiconductor layer; 110. First mesa structure; 120. Second mesa structure; 121. First sidewall; 122. Second sidewall/Sidewall of the epitaxial structure; 200. Ohmic contact layer; 300. Metal stack structure; 301. First metal layer; 302. Second metal layer; 401. First electrode layer; 402. Second electrode layer; 500. Passivation layer; 001. LED; 002. Encapsulation substrate; 010. Light-emitting side; 011. Backlight side.

### DETAILED DESCRIPTION OF EMBODIMENTS

The following describes implementations of the present disclosure through specific embodiments. Those skilled in the art can easily understand other advantages and effects of the present disclosure from the contents disclosed in this specification. The present disclosure can also be implemented or applied through other different specific embodiments. Various details in this specification can be modified or changed based on different perspectives and applications without departing from the spirit of this application. It should be noted that, in the absence of conflict, the following embodiments and the features therein can be combined with each other.

It should be noted that the drawings provided in the embodiments of the present disclosure are only schematic illustrations of the basic concept of the present disclosure. Although the diagrams show only components relevant to the present disclosure and are not drawn according to a number, shapes, and dimensions of components in actual implementation, the morphology, quantity, and proportion of each component during actual implementation can be arbitrarily changed, and the layout of components may be more complex. The structure, proportion, size and so on shown in the drawings of the specification are only used to match the contents disclosed in the specification for people familiar with this technology to understand and read, and are not used to limit the applicable conditions of this application, so they have no technical substantive significance. Any modification of the structure, change of proportion or adjustment of size should still fall within the scope of the technical contents disclosed in this application without affecting the efficacy and objectives that can be achieved by the present disclosure.

The inventors have found that when a magnetic metal structure is disposed in an electrode structure, forming an electrode layer on the magnetic metal structure requires wet etching on the electrode layer. During the wet etching, an etching solution may simultaneously corrode the magnetic metal structure, thereby affecting a surface morphology of the magnetic metal structure. This, in turn, impacts an adhesion between the subsequently formed electrode layer and the magnetic metal structure and the epitaxial structure, leading to detachment or damage of the electrode layer or the magnetic metal structure, which compromises the reliability of the chip. Moreover, when the magnetic metal structure is corroded by the etching solution, detachment or damage will occur to the magnetic metal structure, which may affect the transfer yield of the chip.

To address the issues in the background art and the aforementioned technical problems, the present disclosure provides an LED and a display device, which can enhance the reliability of a magnetic LED, thereby improving transfer yield and efficiency of the LED.

Specifically, the LED includes an epitaxial structure and a metal stack structure. The epitaxial structure includes a first semiconductor layer, an active layer, and a second semiconductor layer. The second semiconductor layer, the active layer, and the first semiconductor layer are sequentially and partially etched downward from a partial surface of the second semiconductor layer facing away from the active layer. A part of a remaining portion of the first semiconductor layer after etching defines a first mesa structure. A remaining portion of the second semiconductor layer after etching, a remaining portion of the active layer after etching, and other part of the remaining portion of the first semiconductor layer after etching define a second mesa structure. The metal stack structure is disposed above the first mesa structure and/or the second mesa structure. The metal stack structure includes alternately arranged first metal layers and second metal layers. The first metal layers are inert metal layers, and the second metal layers are magnetic metal layers. In the LED of the present disclosure, the first metal layers are the inert metal layers, which can resist corrosion from etching solutions in a subsequent process, thereby protecting the metal stack structure. This prevents damage to the metal stack structure from affecting the adhesion of the metal stack structure to the subsequently formed electrode layer, avoiding electrode delamination.

In an embodiment, a layer of the metal stack structure closest to the first mesa structure and/or the second mesa structure is a first layer, and an outermost layer of the metal stack structure farthest from the first mesa structure and/or the second mesa structure is a last layer. Both the first layer and the last layer are the first metal layers. By arranging the first metal layers at top and bottom layers of the metal stack structure, the magnetic metal layers can be encapsulated by the inert metal layers, protecting the magnetic metal layers and preventing an electrode layer formed on the metal stack structure from detaching in a subsequent process, thereby improving the reliability of the LED.

In an embodiment, metal stack structure is disposed above the first mesa structure to prevent the magnetic metal layers from affecting light emission of the LED.

In an embodiment, a thickness of the first layer is less than that of the last layer. Since the last layer is the first to contact the etching solution compared than the first layer, increasing the thickness of the last layer can effectively block the erosion by an etching solution.

In an embodiment, a thickness of each of the first metal layers is less than that of each of the second metal layers.

In an embodiment, a thickness of each of the second metal layers is at least 5 times that of each of the first metal layers, ensuring that the magnetic metal layers of the second metal layers meet magnetic force requirements.

In an embodiment, a volume ratio of the magnetic metal layers to the LED is in a range from 0.8% to 1.2%. Controlling the volume ratio of the magnetic metal layers to the LED within 0.8% to 1.2% enables effective transfer of the chip under a magnetic or electric field.

In an embodiment, a number of the first metal layers is in a range from 3 to 8. Setting the number of the first metal layers in the metal stack structure to 3 to 8 effectively alleviates structural stress in the metal stack structure and improves adhesion.

In an embodiment, a cross-sectional area of the metal stack structure gradually decreases in a direction from the first mesa structure to the metal stack structure, and an angle between an inner sidewall of the metal stack structure and a mesa of the first mesa structure is in a range from 30° to 50°.

In an embodiment, an angle between a sidewall of the epitaxial structure and a plane where the first semiconductor layer is located is in a range from 70° to 90°. In an embodiment, an angle between a sidewall of the second mesa structure and a plane where the first semiconductor layer is located is in a range from 70° to 90°. This sidewall angle configuration, combined with the subsequent metal stack structure, is more conducive to chip transfer.

In an embodiment, a height difference between the first mesa structure and the second mesa structure is ⅓ to ½ of a height of the epitaxial structure. This height difference configuration also facilitates chip transfer.

In an embodiment, a height difference between the first mesa structure and the second mesa structure is in a range from 2.5 μm to 2.8 μm, and a height of the epitaxial structure is in a range from 5.8 μm to 6.3 μm.

In an embodiment, the LED further includes: an ohmic contact layer, disposed between the first mesa structure and the metal stack structure.

In an embodiment, the LED further includes: a first electrode layer disposed on the metal stack structure and electrically connected to the first semiconductor layer; and a second electrode layer disposed on the second mesa structure and electrically connected to the second semiconductor layer.

In an embodiment, a material of each of the first electrode layer and the second electrode layer is a transparent conductive material.

In an embodiment, the first electrode layer extends to cover a sidewall of the first mesa structure, the second mesa structure includes a first sidewall intersecting a mesa of the first mesa structure and a second sidewall, the second sidewall forms a sidewall of the epitaxial structure, the second electrode layer extends from a surface of the second mesa structure to cover the second sidewall, and a covering height of the second electrode layer on the second sidewall is ⅓ to ½ of a sidewall height of the epitaxial structure.

In an embodiment, a passivation layer is disposed on the first and second sidewalls of the second mesa structure, and a part of the second electrode layer covering the sidewall of the epitaxial structure is disposed on the passivation layer.

In an embodiment, the first mesa structure is circumferentially arranged around the second mesa structure, and the metal stack structure extends along a mesa of the first mesa structure to form an annular structure. Due to the arrangement of the annular structure, magnetic metal materials are uniformly distributed on the chip, and the stability of chip transfer is ensured.

The present disclosure further provides a display device, which includes an encapsulation substrate and at least one LED disposed on the encapsulation substrate. A side having an electrode layer of each of the at least one LED is a light-emitting side, and a side opposite to the light-emitting side of each of the at least one LED is a backlight side. The backlight side of each of the at least one LED is connected to the encapsulation substrate, and each of the at least one LED is the LED described above.

The present disclosure is described in detail below with reference to specific embodiments.

### Embodiment 1

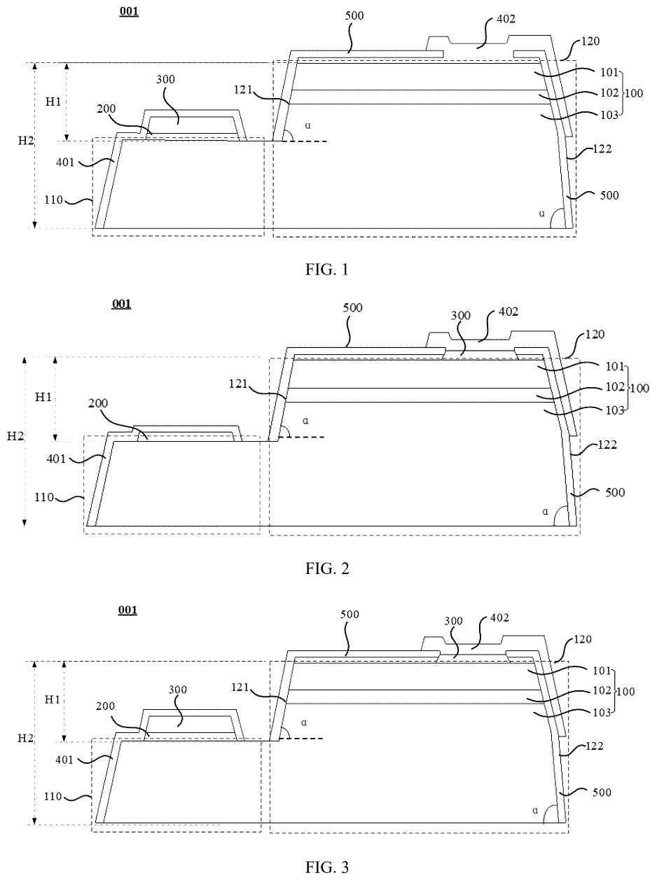

This embodiment provides an LED. Referring to FIG. 1, the LED includes an epitaxial structure 100, and a metal stack structure 300 disposed on the epitaxial structure 100 and electrically connected to the epitaxial structure 100. The metal stack structure 300 includes a magnetic metal material. This magnetic metal stack structure 300 is used to interact with a magnetic or electric field in a transfer environment during subsequent chip transfer, enabling the LED to be transferred to a preset position on a substrate under the action of magnetic or electric force.

Specifically, referring to FIG. 1, the epitaxial structure 100 is a light-emitting unit of the LED. The epitaxial structure 100 sequentially includes a stack structure formed by a first semiconductor layer 103, an active layer 102, and a second semiconductor layer 101. The epitaxial structure 100 includes a first mesa structure 110 and a second mesa structure 120. The second semiconductor layer 101, the active layer 102, and the first semiconductor layer 103 are sequentially and partially etched downward from a partial surface of the second semiconductor layer 101. A part of a remaining portion of the first semiconductor layer 103 after etching defines a first mesa structure 110. A remaining portion of the second semiconductor layer 101 after etching, a remaining portion of the active layer 102 after etching, and other part of the remaining portion of the first semiconductor layer 103 after etching define a second mesa structure 120. The first semiconductor layer 103 can be an N-type semiconductor layer, and the second semiconductor layer 101 can be a P-type semiconductor layer. The first semiconductor layer 103 is used to provide electrons for composite light emission, and the second semiconductor layer 101 is used to provide holes for composite light emission. The active layer 102 is a single quantum well or multiple quantum well for the composite light emission of electrons and holes. Of course, it is also possible for the first semiconductor layer 103 to be a P-type semiconductor layer and the second semiconductor layer 101 to be an N-type semiconductor layer.

In an embodiment, referring to FIG. 1, the first mesa structure 110 is disposed on a side of the epitaxial structure 100, and the second mesa structure 120 is disposed on another side of the epitaxial structure 100. The first mesa structure 110 is formed by etching the epitaxial structure 100. An etch-stop mesa formed by etching from the second semiconductor layer 101 of the epitaxial structure 100 to the first semiconductor layer 103 is a mesa of the first mesa structure 110. A sidewall formed by etching the epitaxial structure 100 is a part of a sidewall of the second mesa structure 120. The part of the sidewall of the second mesa structure 120 is a first sidewall 121 of the second mesa structure 120, and the first sidewall 121 intersects the mesa of the first mesa structure 110. The sidewall of the second mesa structure 120 further includes a second sidewall 122, which becomes a sidewall of the epitaxial structure 100. In an embodiment, an angle α between the sidewall (the second sidewall 122) of the epitaxial structure 100 and a plane where the first semiconductor layer 103 is located is in a range from 70° to 90°, for example, 85°. An angle α between the first sidewall 121 of the second mesa structure 120 and the plane the first semiconductor layer is located is in a range from 70° to 90°, for example, 85°. The aforementioned sidewall angle configuration, combined with the subsequent metal stack structure 300, is more conducive to chip transfer. In an embodiment, a height difference between the first mesa structure 110 and the second mesa structure 120 is ⅓ to ½ of a height of the epitaxial structure 100. This height difference configuration also facilitates chip transfer and improves transfer efficiency. For example, the height difference H1 between the first mesa structure 110 and the second mesa structure 120 is in a range from 2.5 μm to 2.8 μm, and the height H2 of the epitaxial structure 100 is in a range from 5.8 μm to 6.3 μm.

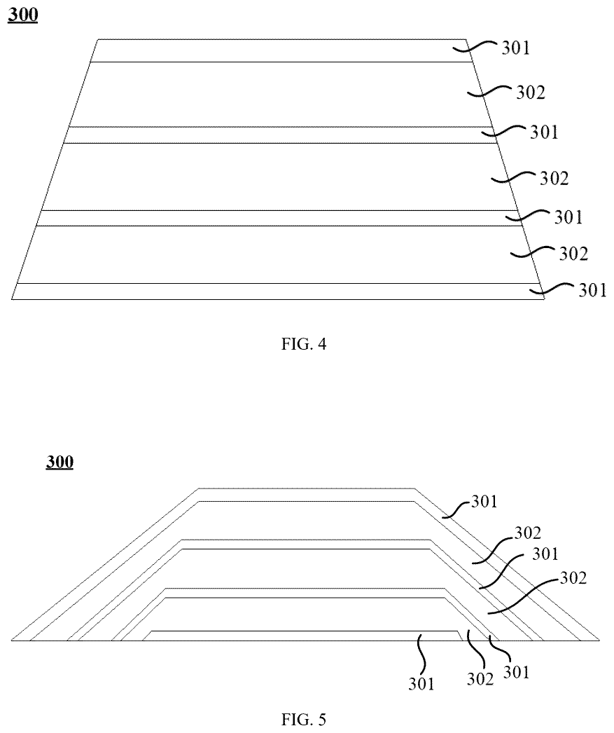

Referring to FIGS. 1-3, the metal stack structure 300 is disposed above the first mesa structure 110 and/or the second mesa structure 120. Referring to FIG. 4, the metal stack structure 300 includes alternately arranged first metal layers 301 and second metal layers 302. The second metal layers 302 are magnetic metal layers, and a volume ratio of the magnetic metal layers to the LED is in a range from 0.8% to 1.2%. This magnetic metal stack structure 300 is used to interact with the magnetic or electric field in the transfer environment during subsequent chip transfer, enabling it to be transferred to a preset position on the substrate under the action of magnetic or electric force. Controlling the volume ratio of the magnetic metal layers to the LED within 0.8% to 1.2% enables effective transfer of the chip under a magnetic or electric field. In this embodiment, to prevent the metal stack structure 300 from absorbing light emitted by the epitaxial structure 100, the metal stack structure 300 is disposed only on the first mesa structure 110. Of course, it is also possible to dispose the metal stack structure 300 on the second mesa structure 120 to achieve a certain purpose at the expense of partially sacrificing the light output of the epitaxial structure.

To prevent unnecessary damage to the metal stack structure 300 during the etching process of the subsequently formed electrode structure, which would affect the bonding between the subsequent electrode and the first mesa structure 110 and avoid electrode detachment, referring to FIG. 4, in an embodiment, a layer of the metal stack structure 300 closest to the first mesa structure 110 is a first layer, and an outermost layer of the metal stack structure 300 farthest from the first mesa structure 110 is a last layer. Both the first layer and the last layer are first metal layers 301. Furthermore, A material of each of the first metal layers 301 is an inert metal material that is not easily etched by an etching solution, to prevent the first layer in contact with the first mesa structure 110 and the last layer in contact with an electrode layer from being damaged by the etching solution, ensuring the adhesion of the electrode layer. In an embodiment, referring to FIG. 5, each first metal layer 301 covers all side surfaces of a magnetic metal layer 32 below the first metal layer 301. Since the magnetic metal layer 302 is covered by the first metal layer 301, compared to the metal stack structure 300 in FIG. 4, the first metal layer 301 protects all the side surfaces of the magnetic metal layer 302 from being corroded by the etching solution, ensuring its magnetism. In an embodiment, since the last metal layer is located on a top and will first contact the etching solution, a thickness of the last metal layer is set to be greater than that of the first layer to better protect the magnetic metal layer from being corroded by the etching solution.

To improve the bonding force or adhesion between the metal stack structure 300 and the first mesa structure 110, this embodiment sets the metal stack structure 300 as a stack structure to alleviate its structural stress and improve adhesion. In an embodiment, as shown in FIG. 4 or 5, a number of the first metal layers 301 is in a range from 3-8 and a number of the second metal layers 302 is one less than the number of the first metal layers 301. In a specific embodiment, the number of the first metal layers 301 is 4, and the number of the second metal layers 302 is 3. To control the thickness of the metal stack structure 300 and ensure its magnetic force, a thickness of the magnetic second metal layers 302 is at least 5 times that of the first metal layers 301, for example, 10 times. In a specific embodiment, the metal stack structure 300 is: first metal layer 301/second metal layer 302/first metal layer 301/second metal layer 302/first metal layer 301/second metal layer 302/first metal layer 301. A material of each first metal layer 301 is platinum, and a material of each second metal layer 302 is nickel. The thickness of the metal stack structure 300 is 80 Å-200 Å/900 Å-1200 Å/80 Å-200 Å/900 Å-1200 Å/80 Å-200 Å/900 Å-1200 Å/100 Å-220 Å, for example: 100 Å/1000 Å/100 Å/1000 Å/100 Å/1000 Å/200 Å. Of course, the material of each first metal layer 301 can also be other inert metal materials that are resistant to etching by the etching solution, and this inert metal material needs to have good adhesion with the first mesa structure 110 or the ohmic contact layer formed on the first mesa structure 110. To achieve good metal bonding force and buffer structural stress, a cross-sectional area of the metal stack structure 300 gradually decreases in a direction from the first mesa structure 110 to the metal stack structure. An angle between an inner sidewall of the metal stack structure 300 and a mesa of the first mesa structure 110 is in a range from 30° and 50°, for example, 40°±3°. Moreover, when the angle between the inner sidewall of the metal stack structure 300 and the mesa of the first mesa structure 110 is between 40°±3°, combined with the aforementioned thickness range setting of the metal stack structure 300, a volume ratio of the magnetic metal layers 302 to the LED is in a range from 0.8% to 1.2% can be achieved to be 0.8%-1.2%.

In an embodiment, the LED further includes an Ohmic contact layer. In a specific embodiment, referring to FIG. 1, an Ohmic contact layer 200 is disposed between the first mesa structure 110 and the metal stack structure 300. A material of the Ohmic contact layer 200 may be one of gold, germanium, or nickel. This Ohmic contact layer 200 has good adhesion with the first metal layer of the metal stack structure 300.

In an embodiment, referring to FIG. 1, the LED further includes a first electrode layer 401 and a second electrode layer 402. The first electrode layer 401 is disposed on the metal stack structure 300 and is connected to the exposed first semiconductor layer 103 of the first mesa structure 110 through the metal stack structure 300. The second electrode layer 402 is disposed on the second mesa structure 120 and is electrically connected to the second semiconductor layer 101 on the second mesa structure 120. Since a light-emitting side of the LED in this embodiment is on the same side as the first and second electrode layers 401 and 402, both the first electrode layer 401 and the second electrode layer 402 are made of transparent conductive materials to ensure light output from the light-emitting side. In an embodiment, each transparent conductive material is ITO.

In an embodiment, referring to FIG. 1, the first electrode layer 401 of the LED is disposed on the first mesa structure 110 and extends to completely cover a sidewall of the first mesa structure 110. The second electrode layer 402 extends from a surface of the second mesa structure 120 to cover the second sidewall 122. A height of the second electrode layer 402 covering the second sidewall 122 is ⅓ to ½ of a sidewall height of the epitaxial structure 100. The first electrode layer 401 and the second electrode layer 402 extending to the sidewall of the epitaxial structure 100 are used to meet backend customer requirements, such as circuit connections for subsequent encapsulation, improving the yield of circuit design after transfer. In an embodiment, a passivation layer 500 is further disposed on the first sidewall 121 and the second sidewall 122 (the sidewall of the epitaxial structure 100) of the second mesa structure 120. The second electrode layer 402 covering the second sidewall 122 is formed on the passivation layer 500. In an embodiment, the passivation layer 500 may be silicon dioxide or silicon nitride. In an embodiment, a material of the passivation layer 500 is silicon dioxide, and a thickness of the passivation layer 500 is 4000 Å.

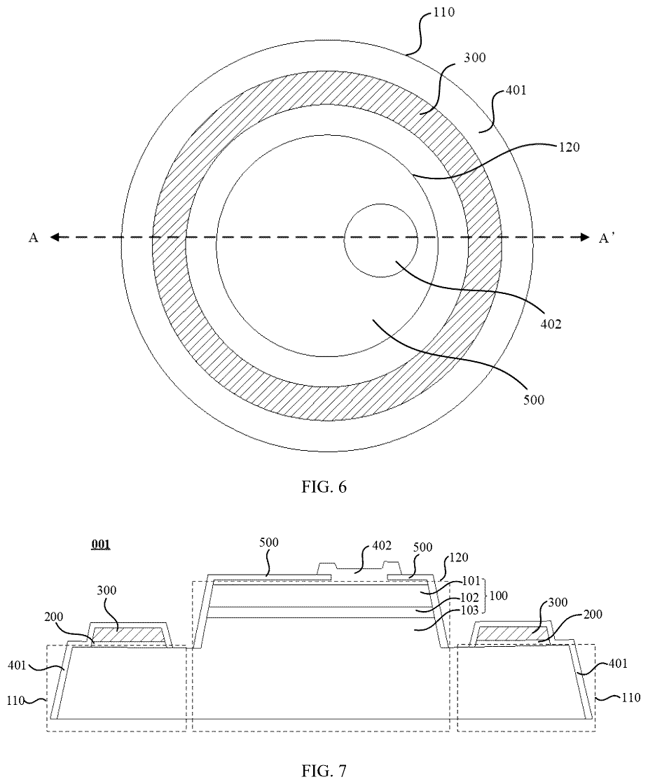

To prevent the chip from rotating during a transfer process and not being transferred smoothly to the preset position on the substrate, in an embodiment, referring to FIGS. 6 and 7, the first mesa structure 110 is circumferentially arranged around the second mesa structure 120. The metal stack structure 300 extends along the mesa of the first mesa structure 110 to form an annular structure. This annular configuration ensures uniform distribution of the magnetic metal material on the chip, guaranteeing stability during chip transfer.

### Embodiment 2

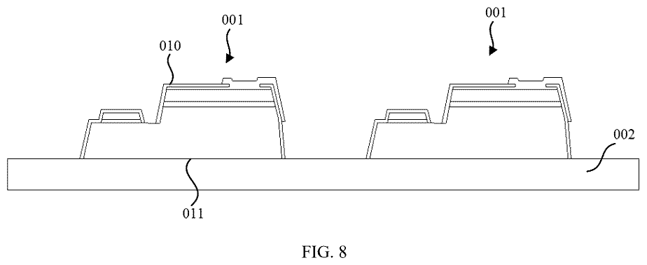

An embodiment of the present disclosure provides a display device. Referring to FIG. 8, the display device includes an encapsulation substrate 002 and at least one LED 001 disposed on the encapsulation substrate 002. A side having an electrode layer of each LED 001 is a light-emitting side 010, and a side opposite the light-emitting side 010 of each LED 001 is a backlight side 011. The backlight side 011 of each LED 001 is connected to the encapsulation substrate 002, and the LED 001 in this embodiment is the LED described in the embodiment 1, the structure of which will not be repeated herein.

The above embodiments are only used to illustrate the principles and effects of the present disclosure and are not intended to limit the present disclosure. Anyone skilled in the art can modify or change the above embodiments without departing from the spirit and scope of the present disclosure. Therefore, all equivalent modifications or changes made by those with ordinary knowledge in the technical field without departing from the spirit and technical ideas disclosed in the present disclosure shall still be covered by the claims of the present disclosure.

What is claimed is:

1. A light emitting diode (LED), comprising:
an epitaxial structure, comprising: a first semiconductor layer, an active layer, and a second semiconductor layer, wherein the second semiconductor layer, the active layer, and the first semiconductor layer are sequentially and partially etched downward from a partial surface of the second semiconductor layer; a part of a remaining portion of the first semiconductor layer after etching defines a first mesa structure; and a remaining portion of the second semiconductor layer after etching, a remaining portion of the active layer after etching, and other part of the remaining portion of the first semiconductor layer after etching define a second mesa structure; and
a metal stack structure, disposed above the first mesa structure and/or the second mesa structure, wherein the metal stack structure comprises alternately arranged first metal layers and second metal layers, the first metal layers are inert metal layers; and the second metal layers are magnetic metal layers.

2. The LED as claimed in claim 1, wherein the metal stack structure is disposed above the first mesa structure, a layer of the metal stack structure closest to the first mesa structure is a first layer, an outermost layer of the metal stack structure farthest from the first mesa structure is a last layer, and the first layer and the last layer each are the first metal layers.

3. The LED as claimed in claim 2, wherein a thickness of the first layer is less than that of the last layer.

4. The LED as claimed in claim 1, wherein a thickness of each of the first metal layers is less than that of each of the second metal layers.

5. The LED as claimed in claim 1, wherein a thickness of each of the second metal layers is at least 5 times that of each of the first metal layers.

6. The LED as claimed in claim 1, wherein a volume ratio of the magnetic metal layers to the LED is in a range from 0.8% to 1.2%.

7. The LED as claimed in claim 2, wherein a number of the first metal layers is in a range from 3 to 8.

8. The LED as claimed in claim 1, wherein a cross-sectional area of the metal stack structure gradually decreases in a direction from the first mesa structure to the metal stack structure, and an angle between an inner sidewall of the metal stack structure and a mesa of the first mesa structure is in a range from 30° to 50°.

9. The LED as claimed in claim 1, wherein an angle between a sidewall of the epitaxial structure and a plane where the first semiconductor layer is located is in a range from 70° to 90°.

10. The LED as claimed in claim 1, wherein an angle between a sidewall of the second mesa structure and a plane where the first semiconductor layer is located is in a range from 70° to 90°.

11. The LED as claimed in claim 1, wherein a height difference between the first mesa structure and the second mesa structure is ⅓ to ½ of a height of the epitaxial structure.

12. The LED as claimed in claim 1, wherein a height difference between the first mesa structure and the second mesa structure is in a range from 2.5 μm to 2.8 μm, and a height of the epitaxial structure is in a range from 5.8 μm to 6.3 μm.

13. The LED as claimed in claim 2, further comprising: an ohmic contact layer, disposed between the first mesa structure and the metal stack structure.

14. The LED as claimed in claim 2, further comprising: a first electrode layer disposed on the metal stack structure and electrically connected to the first semiconductor layer; and a second electrode layer disposed on the second mesa structure and electrically connected to the second semiconductor layer.

15. The LED as claimed in claim 14, wherein a material of each of the first electrode layer and the second electrode layer is a transparent conductive material.

16. The LED as claimed in claim 14, wherein the first electrode layer extends to cover a sidewall of the first mesa structure, the second mesa structure comprises a first sidewall intersecting a mesa of the first mesa structure and a second sidewall, the second sidewall forms a sidewall of the epitaxial structure, the second electrode layer extends from a surface of the second mesa structure to cover the second sidewall, and a covering height of the second electrode layer is ⅓ to ½ of a sidewall height of the epitaxial structure.

17. The LED as claimed in claim 16, wherein a passivation layer is disposed on the first and second sidewalls of the second mesa structure, and a part of the second electrode layer covering the sidewall of the epitaxial structure is disposed on the passivation layer.

18. The LED as claimed in claim 2, wherein the first mesa structure is circumferentially arranged around the second mesa structure, and the metal stack structure extends along a mesa of the first mesa structure to form an annular structure.

19. A display device, comprising: an encapsulation substrate and at least one LED disposed on the encapsulation substrate;
wherein a side having an electrode layer of each of the at least one LED is a light-emitting side, a side opposite to the light-emitting side of each of the at least one LED is a backlight side, the backlight side of each of the at least one LED is connected to the encapsulation substrate, and each of the at least one LED is the LED as claimed in claim 1.

20. The display device as claimed in claim 19, wherein the metal stack structure is disposed above the first mesa structure, a layer of the metal stack structure closest to the first mesa structure is a first layer, an outermost layer of the metal stack structure farthest from the first mesa structure is a last layer, and the first layer and the last layer each are the first metal layers.
